(19) United States
(12) Patent Application Publication
(10) Pub. No.: US 2025/0379164 A1
(43) Pub. Date: Dec. 11, 2025

(54) ELECTRONIC DEVICE

(71) Applicant: InnoLux Corporation, Miao-Li County (TW)

(72) Inventors: Yu-Jhou GONG, Miao-Li County (TW); Jui-Jen YUEH, Miao-Li County (TW); Ju-Li WANG, Miao-Li County (TW); Ti-Chung CHANG, Miao-Li County (TW)

(21) Appl. No.: 19/200,962

(22) Filed: May 7, 2025

(30) Foreign Application Priority Data
Jun. 7, 2024 (CN) 202410736951.9

(51) Int. Cl. H01L 23/00

(52) U.S. Cl. CPC H01L 24/02; H01L 24/04; H01L 2224/02331; H01L 2224/02381; H01L 2224/0401

(57) ABSTRACT

An electronic device includes an electronic unit and a connection structure disposed on the electronic unit. The electronic unit includes an electronic element and a conductive pad electrically connected to the electronic element. The connection structure includes a first pad electrically connected to the conductive pad, a second pad electrically connected to the first pad, and a first polymer surrounding the first pad and the second pad. The first pad includes a first portion, a second portion, and a third portion. The first portion is in contact with the conductive pad, the second portion connects the first portion, and the third portion connects the second portion and extends outwardly with respect to the first portion. The third portion has a first edge adjacent to the conductive pad, and at least a portion of the first edge is inclined toward the conductive pad.

### CROSS REFERENCE TO RELATED APPLICATIONS

This application claims priority of China Patent Application No. 202410736951.9, filed on Jun. 7, 2024, the entirety of which is incorporated by reference herein.

### BACKGROUND OF THE INVENTION

### Field of the Invention

The present invention relates to an electronic device, and in particular, to an electronic device including a connection structure.

### Description of the Related Art

With the development of digital technology, electronic devices are widely used in all aspects of daily life. Most electronic devices include an electronic unit and a connection structure electrically connected to the electronic unit. A conventional connection structure has a large volume and a smooth interface with adjacent elements made of different materials. As a result, the conventional connection structure may crack or delaminate due to the different thermal expansion coefficients and poor adhesion between it and the materials of the adjacent elements.

### BRIEF SUMMARY OF THE INVENTION

An embodiment of the present disclosure provides an electronic device, which includes an electronic unit and a connection structure disposed on the electronic unit. The electronic unit includes an electronic element and a conductive pad electrically connected to the electronic element. The connection structure includes a first pad electrically connected to the conductive pad, a second pad electrically connected to the first pad, and a first polymer surrounding the first pad and the second pad. The first pad includes a first portion, a second portion, and a third portion. The first portion is in contact with the conductive pad, the second portion connects the first portion, and the third portion connects the second portion and extends outwardly with respect to the first portion. A portion of the first polymer is disposed between the third portion and the conductive pad. In a cross-sectional view, the third portion has a first edge adjacent to the conductive pad, and at least a portion of the first edge is inclined toward the conductive pad.

### BRIEF DESCRIPTION OF THE DRAWINGS

The present disclosure can be more fully understood by reading the subsequent detailed description and examples with references made to the accompanying drawings, wherein:

FIG. 1A is a cross-sectional schematic view of an electronic device according to an embodiment of the present disclosure;

FIG. 1B is an enlarged schematic view of a region A of the electronic device shown in FIG. 1A according to an embodiment of the present disclosure;

FIG. 2 is a cross-sectional schematic view of an electronic device according to another embodiment of the present disclosure;

FIG. 3 is a cross-sectional schematic view of an electronic device according to another embodiment of the present disclosure;

FIG. 4 is a cross-sectional schematic view of an electronic device according to yet another embodiment of the present disclosure;

FIG. 5A is a schematic layout view of a first electronic unit, a second electronic unit, and a third electronic unit in an electronic device according to another embodiment of the present disclosure;

FIG. 5B is a cross-sectional schematic view of a first electronic unit and a first connection structure disposed thereon according to an embodiment of the present disclosure;

FIG. 5C is a cross-sectional schematic view of a second electronic unit and a second connection structure disposed thereon according to an embodiment of the present disclosure; and

FIG. 5D is a cross-sectional schematic view of a third electronic unit and a third connection structure disposed thereon according to an embodiment of the present disclosure.

### DETAILED DESCRIPTION OF THE INVENTION

The following description provides various embodiments of the present disclosure to illustrate general principles of the present disclosure and should not be taken in a limiting sense. The scope of the present disclosure is determined by reference to the appended claims. Reference will now be made in detail to exemplary embodiments of the present disclosure, examples of which are illustrated in the accompanying drawings. Whenever possible, the same reference numbers are used in the drawings and descriptions to refer to the same or similar parts.

The present disclosure can be understood by referring to the following detailed description and combined with the accompanying drawings. It should be noted that in order to make it easy for readers to understand and for the simplicity of the accompanying drawings, many of the accompanying drawings in the present disclosure only depict a portion of the electronic device, and certain elements in the accompanying drawings are not drawn to actual scale. For example, the relative sizes and/or thicknesses of various layers, regions and/or structures may be reduced or exaggerated for clarity. In addition, the number and size of each elements in the accompanying drawings are only for illustration and are not intended to limit the scope of the present disclosure.

Directional terms mentioned in the disclosure, such as “up”, “down”, “front”, “back”, “left”, “right” only refer to the directions of the accompanying drawings. Therefore, the directional terms used herein are illustrative and not intended to limit the disclosure. It should be understood that if a device in an accompanying drawing is turned so that it is upside down, elements recited on the “bottom” side will become the elements on the “top” side. In the accompanying drawings, the drawings illustrate general features of the methods, structures and/or materials used in specific embodiments. However, these accompanying drawings should not be construed as defining or limiting the scope or property of what is covered by these embodiments.

In the present disclosure, descriptions of a structure (or layer, element or substrate) being on/above another structure (or layer, element or substrate) may mean that the two structures are adjacent and directly connected, or that the two structures are adjacent and indirectly connected. Indirect connection means that there is at least one intermediate structure (or intermediate layer, intermediate element, intermediate substrate, intermediate spacer) between two structures.

The term “A surrounds B” in the disclosure means that at least a portion of B is in A, and in a cross-sectional view, A at least directly or indirectly contacts a side surface of B. The term “A indirectly contacts B” in the disclosure refers to the existence of an intermediate structure between A and B. The term “A directly contacts B” in the disclosure means that there is no intermediate structure between A and B.

In some embodiments of the present disclosure, unless otherwise defined, terms related to joining and connecting, such as “connection”, “interconnection”, etc., may mean that two structures are in direct contact, or may also mean that the two structures are not in direct contact (indirect contact) and other structures are between the two structures. Indirect connection means that there is at least one intermediate structure (or intermediate layer, intermediate element, intermediate substrate, intermediate spacer) between two structures. The intermediate structure may be a single-layer or multi-layer physical structure or may be composed of non-physical structures, without limitation. The terms related to joining and connecting may also include the situation where both structures are movable or both structures are fixed. In addition, the term “electrical connection” includes the transfer of energy between two structures by direct or indirect electrical connection, or the transfer of energy between two separate structures by mutual induction.

In the disclosure, the terms “about”, “equal to”, “equal” or “the same”, “substantially” or “approximately” usually indicates a value of a given value or range that varies within 20%, or a value of a given value or range that varies within 10%, within 5%, or within 3%, or within 2%, or within 1%, or within 0.5%. The term “a-b” refers to a range that includes all values greater than or equal to a, less than or equal to b, and all values between a and b.

Ordinal numbers used in the specification and claims, such as “first”, “second”, etc., are used to modify elements. The ordinal numbers do not imply or represent numbers of the element (or elements). The ordinal numbers do not represent the order of one element over another or the order of manufacturing method. The ordinal numbers are only used to clearly distinguish two elements having the same name. The claims and the specification may not use the same terms. Therefore, the first element in the specification may be the second element in the claim.

Throughout the disclosure and the appended claims, some terms are used to refer to specific elements. Those skilled in the art will understand that manufacturers may refer to the same element by different names. The disclosure is not intended to differentiate between elements that have the same function but have different names.

Unless otherwise defined, all terms (including technical and scientific terms) used herein have the same meaning as commonly understood by a person skilled in the art to which the disclosure pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

The electronic device may include a power module, an imaging device, a semiconductor device, a display device, a light emitting device, a backlight device, an antenna device, a sensing device, a packaging device, a splicing device, a touch electronic device, a curved electronic device or a free shape electronic device, but is not limited thereto. The electronic device may include, for example, liquid crystals, light emitting diodes, fluorophors, phosphors, other suitable display medias, or any combination of thereof, but are not limited thereto. The display device may be a non-self-luminous display device or a self-luminous display device. The antenna device may be a liquid crystal type antenna device or a non-liquid crystal type antenna device. The sensing device may be a sensing device that senses capacitance, light, heat energy or ultrasonic waves, but is not limited thereto. The splicing device may be, for example, a display splicing device or an antenna splicing device, but is not limited thereto.

The electronic device may be a bendable or flexible electronic device. The shape of the electronic device may be a rectangular shape, a circular shape, a polygonal shape, a shape with curved edges, or other suitable shapes. The processes of the electronic devices described in the present disclosure may be applied, for example, in a wafer-level package process (WLP) or a panel-level package (PLP) process, either a chip first process or a chip last (RDL first) process.

The electronic unit of the present disclosure may include electronic elements. The electronic elements may include passive elements, active elements, or a combination thereof. For example, the electronic elements may include capacitors, resistors, inductors, varactor diodes, variable capacitors, filters, diodes, transistors, sensors, microelectromechanical system (MEMS) elements, semiconductor chips, etc., but are not limited thereto. The diodes may include light emitting diodes or non-light emitting diodes. The diodes may include P-N junction diodes, PIN diodes or constant current diodes. The light emitting diodes may include, for example, organic light emitting diodes (OLEDs), submillimeter light emitting diodes (mini LEDs), micro light emitting diodes (micro LEDs), quantum dot light emitting diodes (quantum dot LEDs), fluorescence diodes, phosphor diodes, or any combination of thereof, but are not limited thereto. The sensing device may include, for example, capacitive sensors, optical sensors, electromagnetic sensors, fingerprint sensors (FPS), touch sensors, antennas, or pen sensors, or any combination of thereof, but are not limited to thereto.

It should be understood that according to the embodiments of the present disclosure, the depth, thickness, width or height of each element, or the space of the components or the distance between them may be measured using an optical microscope (OM), a scanning electron microscope (SEM), a film thickness profile measuring gauge (α-step), an elliptical thickness gauge, or other suitable measurement methods. According to some embodiments, a scanning electron microscope may be used to obtain a cross-sectional structural image including the components to be measured, and to measure the depth, thickness, width or height of each component, or the space or distance between the components.

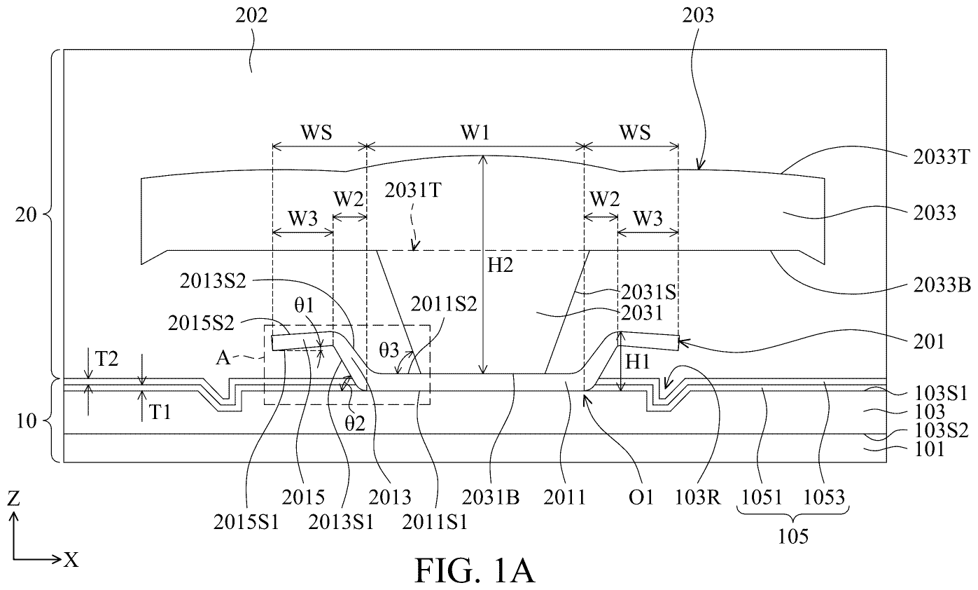

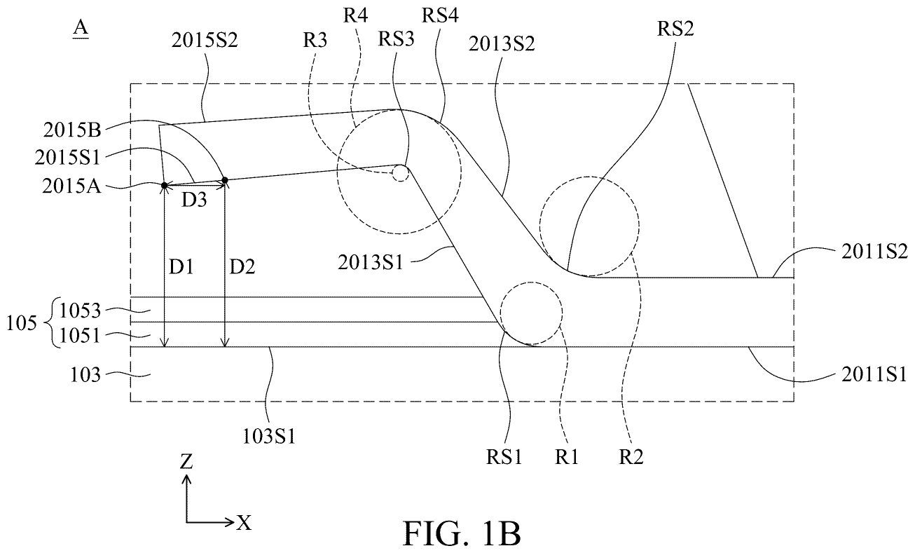

An embodiment of the present disclosure provides an electronic device. FIG. 1A is a cross-sectional schematic view of an electronic device according to an embodiment of the present disclosure. FIG. 1B is an enlarged schematic view of a region A of the electronic device shown in FIG. 1A according to an embodiment of the present disclosure. The term “cross-sectional view/cross-sectional schematic view” used herein refers to a view/schematic view taken along a normal direction (i.e., Z direction) of the electronic device.

As shown in FIG. 1A, the electronic device of the present disclosure includes an electronic unit 10 and a connection structure 20 disposed on the electronic unit 10. The electronic unit 10 includes an electronic element 101 and a conductive pad 103 electrically connected to the electronic element 101. The connection structure 20 includes a first pad 201 electrically connected to the conductive pad 103, a second pad 203 electrically connected to the first pad 201, and a first polymer 202 surrounding the first pad 201 and the second pad 203. The first pad 201 includes a first portion 2011, a second portion 2013, and a third portion 2015. The first portion 2011 is in contact with the conductive pad 103, the second portion 2013 connects the first portion 2011, and the third portion 2015 connects the second portion 2013 and extends outwardly with respect to the first portion 2011. A portion of the first polymer 202 is disposed between the third portion 2015 and the conductive pad 103. In a cross-sectional view, the third portion 2015 has a first edge 2015S1 adjacent to the conductive pad 103, and at least a portion of the first edge 2015S1 is inclined toward the conductive pad 103.

In some embodiments, the electronic element 101 may include a diode; a semiconductor chip; a light-emitting diode chip (LED die); or a chip made of silicon (Si), gallium arsenide (GaAs), gallium nitride (GaN), silicon carbide (SiC), sapphire or a glass substrate, but the disclosure is not limited thereto. The chip can be any flip-chip bonding element, such as integrated circuits (ICs), transistors, controlled silicon rectifiers, valves, thin film transistors, capacitors, inductors, variable capacitors, filters, resistors, diodes, microelectromechanical system (MEMS) elements, or any combination thereof, but the disclosure is not limited thereto. The chip may include a semiconductor packaging element, such as a ball grid array (BGA) packaging element, a chip size package (CSP) element, a system on package (SoC), a flip chip, an antenna in package (AiP), or a 2.5D/3-dimensional (2.5D/3D) semiconductor packaging element, but the disclosure is not limited thereto. The chip may be a known good die (KGD), which may include lines, transistors, and/or circuit boards. The semiconductor chip may include a system on chip (SoC), a co-packaged optics (CPO) or an application-specific integrated circuit (ASIC), a dynamic random-access memory (DRAM), a high bandwidth memory (HBM), a photonic integrated circuit (PIC), an application-specific integrated circuit (ASIC), or other logic integrated circuits, but the present disclosure is not limited thereto. In some embodiments, the semiconductor chip may be a die that has not been packaged, but the present disclosure is not limited thereto.

In the normal direction of the electronic device (i.e., the Z direction), the conductive pad 103 may be disposed between the electronic element 101 and the first pad 201 of the connection structure 20. The electronic element 101 may be electrically connected to the connection structure 20 through the conductive pad 103. Specifically, the conductive pad 103 may include a first surface 103S1 and a second surface 103S2 opposite the first surface 103S1. The electronic element 101 may be disposed on the second surface 103S2 of the conductive pad 103, and the connection structure 20 may be disposed on the first surface 103S1 of the conductive pad 103. The conductive pad 103 may include a single-layer structure or a multi-layer structure having a plurality of layers. In some embodiments, the conductive pad 103 may include a seed layer, a metal, a metal oxide, or any combination thereof. In some embodiments, examples of the metal may include copper (Cu), aluminum (Al), molybdenum (Mo), tungsten (W), gold (Au), chromium (Cr), nickel (Ni), platinum (Pt), titanium (Ti), silver (Ag), tantalum (Ta), other suitable metal materials or any combination thereof, but the disclosure is not limited thereto.

In some embodiments, the electronic unit 10 of the present disclosure may further include a passivation layer 105 disposed on the conductive pad 103, and the passivation layer 105 has an opening O1 through which the first pad 201 can be electrically connected to the conductive pad 103. The passivation layer 105 may include a single-layer structure or a multi-layer structure having a plurality of layers. In some embodiments, the passivation layer 105 may include a first layer 1051 and a second layer 1053 disposed on the first layer 1051, as shown in FIG. 1A. In the Z direction, the first layer 1051 of the passivation layer 105 has a first thickness T1, and the second layer 1053 has a second thickness T2. In some embodiments, the first thickness T1 of the first layer 1051 of the passivation layer 105 is greater than the second thickness T2 of the second layer 1053, but the present disclosure is not limited thereto. In some embodiments, the ratio of the first thickness T1 to the second thickness T2 (T1/T2) is greater than 1 and less than or equal to 2. In some embodiments, the ratio of the first thickness T1 to the second thickness T2 (T1/T2) is greater than 1 and less than or equal to 1.5. In some embodiments, the first layer 1051 includes a silicon oxide and the second layer 1053 includes a silicon nitride. Accordingly, the first layer 1051, which is easily embrittled by oxidation during the manufacture of the electronic device, can be protected by the second layer 1053. In some embodiments, the conductive pad 103 may include a recess 103R, the passivation layer 105 may be conformally disposed on the conductive pad 103 and in the recess 103R. A portion of the first polymer 202 may be disposed in the recess 103R to increase an adhesion between the passivation layer 105 and the conductive pad 103 and an adhesion between the passivation layer 105 and the first polymer 202, as shown in FIG. 1A.

The connection structure 20 includes a first pad 201, a second pad 203, and a first polymer 202 surrounding the first pad 201 and the second pad 203. The first pad 201 and the second pad 203 may include a single-layer structure or a multi-layer structure having a plurality of layers. In some embodiments, the first pad 201 and the second pad 203 may include a seed layer, a metal, a metal oxide, or any combination thereof. Examples of the metal are described above and will not be repeated herein. The first pad 201 and the second pad 203 may include the same or different materials. In the normal direction of the electronic device (i.e., the Z-direction), the first pad 201 may be disposed between the conductive pad 103 and the second pad 203, and the conductive pad 103 and the second pad 203 may be electrically connected to each other via the first pad 201.

The first pad 201 includes a first portion 2011, a second portion 2013, and a third portion 2015. The first portion 2011 contacts the conductive pad 103, the third portion 2015 does not contact the conductive pad 103, and the second portion 2013 connects the first portion 2011 and the third portion 2015. In some embodiments, in the cross-sectional view, the third portions 2015 are disposed on both sides of the first portion 2011, and the second portions 2013 connect the first portion 2011 and the third portions 2015. The first portion 2011 has a first edge 2011S1 contacting the conductive pad 103 and a second edge 2011S2 opposite the first edge 2011S1. The third portion 2015 has a first edge 2015S1 adjacent to the conductive pad 103 and a second edge 2015S2 opposite the first edge 2015S1. The second portion 2013 has a first edge 2013S1 and a second edge 2013S2. The first edge 2013S1 of the second portion 2013 is between the first edge 2011S1 of the first portion 2011 and the first edge 2015S1 of the third portion 2015. The second edge 2013S2 of the second portion 2013 is between the second edge 2011S2 of the first portion 2011 and the second edge 2015S2 of the third portion 2015.

In some embodiments, the first pad 201 has a first rounded edge RS1, a second rounded edge RS2, a third rounded edge RS3, and a fourth rounded edge RS4, as shown in FIG. 1B, but the present disclosure is not limited thereto. The first rounded edge RS1 connects the first edge 2011S1 of the first portion 2011 to the first edge 2013S1 of the second portion 2013. The second rounded edge RS2 connects the second edge 2011S2 of the first portion 2011 to the second edge 2013S2 of the second portion 2013. The third rounded edge RS3 connects the first edge 2015S1 of the third portion 2015 to the first edge 2013S1 of the second portion 2013. The fourth rounded edge RS4 connects the second edge 2015S2 of the third portion 2015 to the second edge 2013S2 of the second portion 2013. The first rounded edge RS1 and the second rounded edge RS2 can avoid stress concentration or charge accumulation at the connection between the first portion 2011 and the second portion 2013. The third rounded edge RS3 and the fourth rounded edge RS4 can avoid stress concentration or charge accumulation at the connection between the second portion 2013 and the third portion 2015. Therefore, the risk of cracking or delamination of the connection structure 20 and the electrostatic discharge may be reduced.

The first rounded edge RS1 has a first radius of curvature R1, the second rounded edge RS2 has a second radius of curvature R2, the third rounded edge RS3 has a third radius of curvature R3, and the fourth rounded edge RS4 has a fourth radius of curvature R4. In some embodiments, the first radius of curvature R1 of the first rounded edge RS1 may be smaller than the second radius of curvature R2 of the second rounded edge RS2, but the present disclosure is not limited thereto. In the case that the first radius of curvature R1 is smaller than the second radius of curvature R2, the stress concentrated at the connection between the first portion 2011 and the second portion 2013 can be dispersed, so that the risk of cracking or delamination of the connection structure 20 may be reduced. In some embodiments, the ratio (R1/R2) of the first radius of curvature R1 to the second radius of curvature R2 may be greater than or equal to 0.3 and less than 1, but the present disclosure is not limited thereto. In some embodiments, the third radius of curvature R3 of the third rounded edge RS3 may be smaller than the fourth radius of curvature R4 of the fourth rounded edge RS4, but the present disclosure is not limited thereto. In the case that the third radius of curvature R3 is smaller than the fourth radius of curvature R4, the stress concentrated at the connection between the second portion 2013 and the third portion 2015 can be dispersed, so that the risk of cracking or delamination of the connection structure 20 may be reduced. In some embodiments, the ratio of the third radius of curvature R3 to the fourth radius of curvature R4 (R3/R4) may be greater than or equal to 0.1 and less than 1, but the present disclosure is not limited thereto.

In some embodiments, at least a portion of the first edge 2015S1 of the third portion 2015 is inclined toward the conductive pad 103. Thereby, the adhesion between the first pad 201 and the first polymer 202 may be improved, and the risk of deflection, cracking, or delamination of the first pad 201 due to stress may be reduced. In some embodiments, at least a portion of the first edge 2015S1 of the third portion 2015 is inclined toward the conductive pad 103 at an inclination angle greater than 0 degrees and less than or equal to 20 degrees relative to the extending direction of the edge of the conductive pad 103. That is, there is a first angle θ1 between the at least a portion of the first edge 2015S1 of the third portion 2015 and the extending direction of the edge of the conductive pad 103. The first angle θ1 may be greater than 0 degrees and less than or equal to 20 degrees, but the present disclosure is not limited thereto. In this embodiment, the term “an extending direction of an edge of the conductive pad 103” is substantially equal to a first direction (e.g., the X direction), which is perpendicular to the Z direction, but the present disclosure is not limited thereto.

In some embodiments, the first edge 2015S1 of the third portion 2015 has a first endpoint 2015A and a second endpoint 2015B spaced apart from the first endpoint 2015A. A point on the first edge 2015S1 that is farthest away from the first portion 2011 of the first pad 201 is defined as the first endpoint 2015A. In the Z-direction, a first distance D1 between the first endpoint 2015A and the first surface 103S1 of the conductive pad 103 may be smaller than a second distance D2 between the second endpoint 2015B and the first surface 103S1 of the conductive pad 103, as illustrated in FIG. 1B. In some embodiments, the difference between the first distance D1 and the second distance D2 may be greater than 0 μm and less than 2 μm. In the cross-sectional view, the first endpoint 2015A is separated from the second endpoint 2015B by a third distance D3 in the first direction (X-direction), as shown in FIG. 1B. In some embodiments, the third distance D3 may be greater than 0 μm and less than or equal to 5 μm.

In the first direction (X-direction), a first portion 2011 of the first pad 201 has a first width W1. Third portions 2015 disposed on both sides of the first portion 2011 each have a third width W3 respectively, and the second portions 2013 connecting the first portion 2011 and the third portions 2015 on the both sides of the first portion 2011 each have a second width W2 respectively. The sum of the second width W2 and the third width W3 on one side of the first portion 2011 is defined as the width sum WS, as shown in FIG. 1A. That is, in the extending direction (e.g., the X direction) of the edge of the conductive pad 103, the vertical projection of the first portion 2011 onto the conductive pad 103 has a first width W1. Vertical projections of the third portions 2015 on the both sides of the first portion 2011 onto the conductive pad 103 each have a third width W3 respectively. Vertical projections of the second portions 2013 connecting the first portion 2011 and the third portions 2015 on the both sides of the first portion 2011 onto the conductive pad 103 each have a second width W2 respectively. The sum of the second width W2 and the third width W3 on one side of the first portion 2011 is defined as the width sum WS. In some embodiments, the ratio (WS/W1) of the width sum WS of the second width W2 and the third width W3 on one side to the first width W1 may be greater than or equal to 0.2 and less than or equal to 0.6. In the case that the ratio (WS/W1) of the width sum WS to the first width W1 is greater than or equal to 0.2, an adhesion between the first pad 201 and the first polymer 202 may be improved. In the case that the ratio (WS/W1) of the width sum WS to the first width W1 is less than or equal to 0.6, the effect of stress due to thermal expansion and contraction of the first pad 201 may be reduce. Therefore, the risk of cracking or delamination between the first pad 201 and the first polymer 202 may be reduced.

The second pad 203 is disposed on the first portion 2011 of the first pad 201 and is in contact with the second edge 2011S2 of the first portion 2011. The second pad 203 may include a lower portion 2031 and an upper portion 2033. In the Z direction, the lower portion 2031 is disposed between the upper portion 2033 and the first portion 2011 of the first pad 201. The upper portion 2033 has a bottom surface 2033B and a top surface 2033T opposite the bottom surface 2033B, where a portion of the bottom surface 2033B contacts the lower portion 2031. In some embodiments, the top surface 2033T of the upper portion 2033 may have a concave-convex structure, but the present disclosure is not limited thereto. In other words, in the cross-sectional view, the second pad 203 has a non-linear edge that is located away from the first pad 201, as shown in FIG. 1A. The concave-convex structure or non-linear edge may increase a contact area between the top surface 2033T of the upper portion 2033 and the first polymer 202, thereby increasing the adhesion between the second pad 203 and the first polymer 202 and reducing the risk of breakage or delamination of the connection structure 20.

The lower portion 2031 has a bottom surface 2031B in contact with the first portion 2011 of the first pad 201, a top surface 2031T opposite the bottom surface 2031B, and a side edge 2031S connecting the bottom surface 2031B to the top surface 2031T. In some embodiments, in the first direction, a width of the bottom surface 2033B of the upper portion 2033 is greater than a width of the top surface 2031T of the lower portion 2031. At least a portion of the bottom surface 2033B of the upper portion 2033 is in contact with the top surface 2031T of the lower portion 2031. In some embodiments, at least a portion of the bottom surface 2033B of the upper portion 2033 that is not in contact with the top surface 2031T of the lower portion 2031 is tilted toward the conductive pad 103, as shown in FIG. 1A, but the present disclosure is not limited thereto. By tilting at least a portion of the bottom surface 2033B of the upper portion 2033 towards the conductive pad 103, the adhesion between the second pad 203 and the first polymer 202 may be improved, and the risk of deflection, breakage, or delamination of the second pad 203 due to stress may be reduced.

In some embodiments, in the first direction, the width of the bottom surface 2031B of the lower portion 2031 may be less than the width of the top surface 2031T of the lower portion 2031. In some embodiments, the lower portion 2031 of the second pad 203 has an inverted trapezoidal shape, but the present disclosure is not limited thereto. In some embodiments, the first pad 201 has a maximum thickness of H1 and the second pad 203 has a maximum thickness of H2. The maximum thickness H1 of the first pad 201 is, in the Z-direction, the maximum distance between the first edge 2011S1 of the first portion 2011 and the second edge 2015S2 of the third portion 2015. The maximum thickness H2 of the second pad 203 is, in the Z direction, the maximum distance between the bottom surface 2031B of the lower portion 2031 and the top surface 2033T of the upper portion 2033. In some embodiments, the maximum thickness H1 of the first pad 201 is less than the maximum thickness H2 of the second pad 203, but the present disclosure is not limited thereto. In some embodiments, in the first direction, the width of a vertical projection of the lower portion 2031 of the second pad 203 on the conductive pad 103 is less than the width of a vertical projection of the first portion 2011 of the first pad 201 on the conductive pad 103. In some embodiments, in the first direction, the width of a vertical projection of the upper portion 2033 of the second pad 203 on the conductive pad 103 is greater than the width of the vertical projection of the entire first pad 201 on the conductive pad 103, but the present disclosure is not limited thereto.

A second angle θ2 is between the first edge 2013S1 of the second portion 2013 of the first pad 201 and the first surface 103S1 of the conductive pad 103. A third angle θ3 is between the side edge 2031S of the lower portion 2031 and the second edge 2011S2 of the first portion 2011. In some embodiments, the third angle θ3 is greater than the second angle θ2, but the present disclosure is not limited thereto. The third angle θ3 being larger than the second angle θ2 allows the connection structure 20 to have a better structural resistance strength. In some embodiments, the ratio of the second angle θ2 to the third angle θ3 (θ2/θ3) may be greater than or equal to 0.6 and less than or equal to 0.95.

The first polymer 202 surrounds the first pad 201 and the second pad 203. In some embodiments, the first polymer 202 may include photosensitive polyimide (PSPI), polyimide (PI), Ajinomoto build-up film (ABF), polybenzoxazole (PBO), other suitable materials, or any combination thereof, but the present disclosure is not limited thereto. In some embodiments, the first polymer 202 contacts at least portions of the second edge 2011S2 of the first portion 2011, the first edge 2013S1 and the second edge 2013S2 of the second portion 2013, the first edge 2015S1 and the second edge 2015S2 of the third portion 2015, the side edge 2031S of the lower portion 2031, at least portions of the bottom surface 2033B of the upper portion 2033, and the top surface 2033T of upper portion 2033, but the present disclosure is not limited thereto. In some embodiments, a portion of the first polymer 202 may be disposed between the first pad 201 and the second pad 203 and/or between the first pad 201 and the conductive pad 103. By bringing the first polymer 202 into contact with at least one edge or surface of the first pad 201 and/or the second pad 203 having the structures described above, the adhesion between the first polymer 202 and the first pad 201 and/or the second pad 203 having the structures described above may be improved, thereby reducing the risk of breakage or delamination of the connection structure 20.

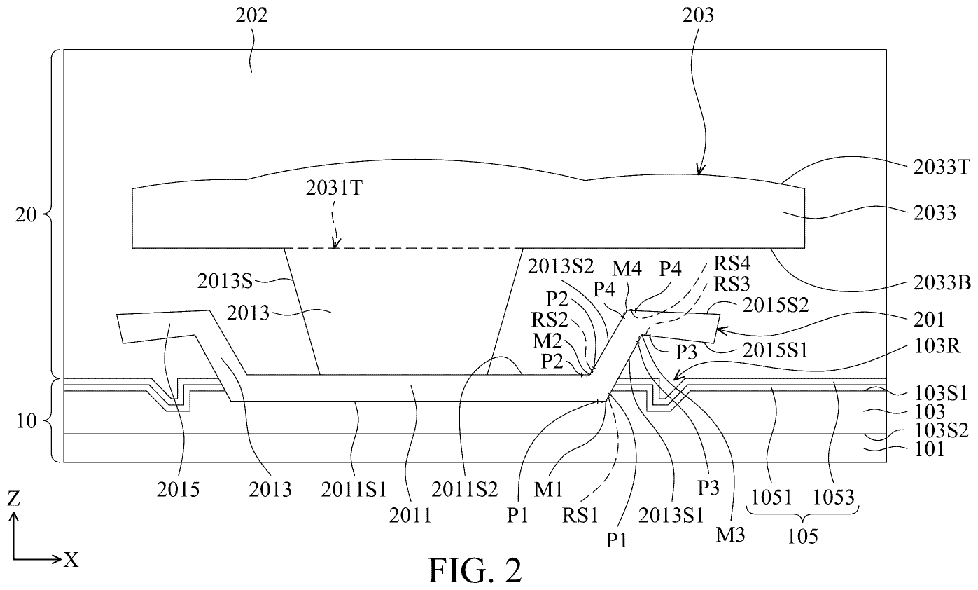

FIG. 2 is a cross-sectional schematic view of an electronic device according to another embodiment of the present disclosure. Except that the first pad 201 has an obvious turning point and the bottom surface 2033B of the upper portion 2033 is not inclined toward the conductive pad 103, the electronic device shown in FIG. 2 is substantially the same as the electronic device shown in FIGS. 1A and 1B. Therefore, only a first turning point M1, a second turning point M2, a third turning point M3, and a fourth turning point M4 of the first pad 201 are described below.

As shown in FIG. 2, the first pad 201 has the first turning point M1, the second turning point M2, the third turning point M3, and the fourth turning point M4. The first turning point M1 is between the first edge 2011S1 of the first portion 2011 and the first edge 2013S1 of the second portion 2013 and connects the first edge 2011S1 of the first portion 2011 and the first edge 2013S1 of the second portion 2013. The second turning point M2 is between the second edge 2011S2 of the first portion 2011 and the second edge 2013S2 of the second portion 2013 and connects the second edge 2011S2 of the first portion 2011 and the second edge 2013S2 of the second portion 2013. The third turning point M3 is between the first edge 2015S1 of the third portion 2015 and the first edge 2013S1 of the second portion 2013 and connects the first edge 2015S1 of the third portion 2015 and the first edge 2013S1 of the second portion 2013. The fourth turning point M4 is between the second edge 2015S2 of the third portion 2015 and the second edge 2013S2 of the second portion 2013 and connects the second edge 2015S2 of the third portion 2015 and the second edge 2013S2 of the second portion 2013. In this embodiment, a rounded edge is defined by a turning point and two end points that are 1 μm apart on either side of the turning point. For example, a first rounded edge RS1 is defined by the first turning point M1 and two end points P1, which are 1 μm apart on either side of the first turning point M1; a second rounded edge RS2 defined by the second turning point M2 and two end points P2, which are 1 μm apart on either side of the second turning point M2; a third rounded edge RS3 is defined by the third turning point M3 and two end points P3, which are 1 μm apart on either side of the third turning point M3; and a fourth rounded edge RS4 is defined by the fourth turning point M4 and two end points P4, which are 1 μm apart on either side of the fourth turning point M4, as shown in FIG. 2.

The first rounded edge RS1 defined above has a first radius of curvature R1, the second rounded edge RS2 has a second radius of curvature R2, the third rounded edge RS3 has a third radius of curvature R3, and the fourth rounded edge RS4 has a fourth radius of curvature R4. In some embodiments, the first radius of curvature R1 of the first rounded edge RS1 may be smaller than the second radius of curvature R2 of the second rounded edge RS2, but the disclosure is not limited thereto. The first radius of curvature R1 being smaller than the second radius of curvature R2 can disperse the stress concentrated at the connection between the first portion 2011 and the second portion 2013 and reduce the risk of cracking or delamination of the connection structure 20. In some embodiments, the ratio of the first radius of curvature R1 to the second radius of curvature R2 (R1/R2) may be greater than or equal to 0.3 and less than 1, but the disclosure is not limited thereto. In some embodiments, the third radius of curvature R3 of the third rounded edge RS3 may be smaller than the fourth radius of curvature R4 of the fourth rounded edge RS4, but the disclosure is not limited thereto. The third radius of curvature R3 being smaller than the fourth radius of curvature R4 can disperse the stress concentrated at the connection between the second portion 2013 and the third portion 2015 and reduce the risk of cracking or delamination of the connection structure 20. In some embodiments, the ratio of the third radius of curvature R3 to the fourth radius of curvature R4 (R3/R4) may be greater than or equal to 0.1 and less than 1, but the disclosure is not limited thereto.

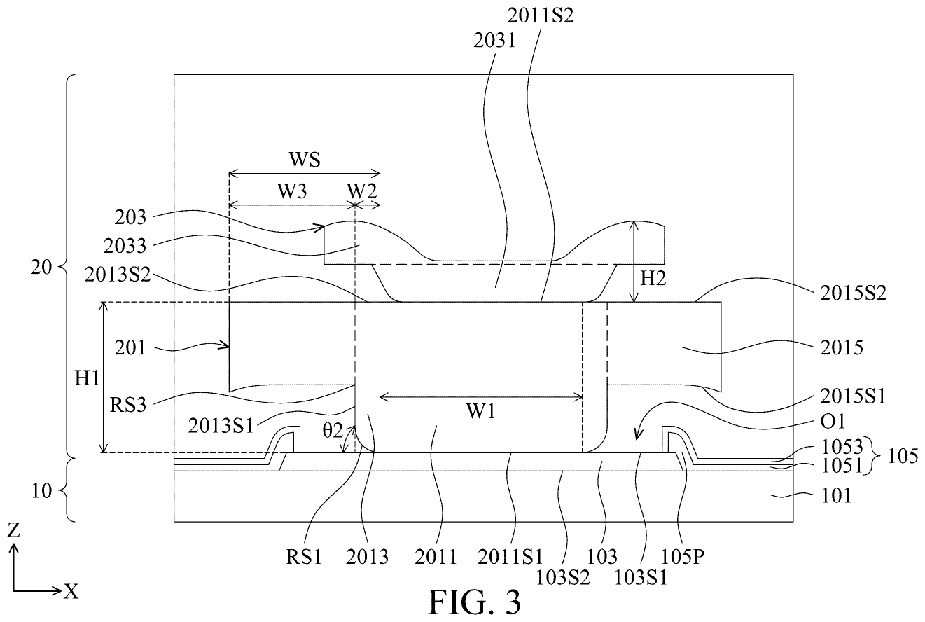

FIG. 3 is a cross-sectional schematic view of an electronic device according to another embodiment of the present disclosure. Except that the shape of the conductive pad 103 of the electronic unit 10 and the structure of the connection structure 20 is different from that of the electronic device shown in FIGS. 1A and 1B, the electronic device shown in FIG. 3 is substantially the same as the electronic device shown in FIGS. 1A and 1B. Therefore, only the shape of the conductive pad 103 of the electronic unit 10 and the first pad 201 and the second pad 203 of the connection structure 20 are further described.

As shown in FIG. 3, the electronic device of the present disclosure includes an electronic unit 10 and a connection structure 20 disposed on the electronic unit 10. In the normal direction of the electronic device (i.e., the Z direction), the conductive pad 103 may be disposed between the electronic element 101 and the first pad 201 of the connection structure 20. The electronic element 101 may be electrically connected to the connection structure 20 through the conductive pad 103. The passivation layer 105 has an opening O1. In some embodiments, a portion of the passivation layer 105 may be extended onto a portion of the conductive pad 103 and form a protrusion 105P surrounding the opening O1, as shown in FIG. 3. The protrusion 105P can increase the adhesion between the passivation layer 105 and the conductive pad 103 and the passivation layer 105 and the first polymer 202.

As shown in FIG. 3, the first pad 201 of the connection structure 20 of the present disclosure includes a first portion 2011, a second portion 2013, and a third portion 2015, where the first portion 2011 is in contact with the conductive pad 103, and the third portion 2015 is not in contact with the conductive pad 103 and extends outward relative to the first portion 2011, and the second portion 2013 connects the first portion 2011 and the third portion 2015. The first portion 2011 has a first edge 2011S1 that contacts the conductive pad 103 and a second edge 2011S2 opposite the first edge 2011S1. The third portion 2015 has a first edge 2015S1 close to the conductive pad 103 and a second edge 2015S2 opposite the first edge 2015S1. The second portion 2013 has a first edge 2013S1 and a second edge 2013S2. In some embodiments, the second edge 2013S2 of the second portion 2013 may be coplanar with the second edge 2011S2 of the first portion 2011, as shown in FIG. 3, but the present disclosure is not limited thereto. In some embodiments, the second edge 2013S2 of the second portion 2013 may be coplanar with the second edge 2015S2 of the third portion 2015, as shown in FIG. 3, but the present disclosure is not limited thereto. In some embodiments, the second angle θ2 between the first edge 2013S1 of the second portion 2013 and the first surface 103S1 of the conductive pad 103 may be approximately 90 degrees, as shown in FIG. 3, but the present disclosure is not limited thereto.

In the first direction (X direction), the first portion 2011 has a first width W1. Each of the third portions 2015 on both sides of the first portion 2011 has a third width W3 respectively. Each of the second portions 2013 connects the third portions 2015 on both sides of the first portion 2011 has a second width W2 respectively. The sum of the second width W2 and the third width W3 on one side of the first portion 2011 is defined as a width sum WS, as shown in FIG. 3. That is, in the extending direction of the edge of the conductive pad 103 (for example, the X direction), the vertical projection of the first portion 2011 on the conductive pad 103 has the first width W1. Each of the vertical projections of the third portions 2015 on both sides of the first portion 2011 has a third width W3 respectively. Each of the vertical projections of the second portion 2013 connects the third portions 2015 on both sides of the first portion 2011 has a second width W2 respectively. The sum of the second width W2 and the third width W3 on one side of the first portion 2011 is defined as a width sum WS. In some embodiments, the ratio of the width sum WS of the second width W2 and the third width W3 on one side to the first width W1 (WS/W1) may be greater than or equal to 0.2 and less than or equal to 0.6. The ratio of the width sum WS to the first width W1 (WS/W1) greater than or equal to 0.2 can improve the adhesion between the first pad 201 and the first polymer 202. The ratio of the width sum WS to the first width W1 (WS/W1) less than or equal to 0.6 can reduce the stress on the first pad 201 due to thermal expansion and contraction, thereby reducing the risk of cracking or delamination between the first pad 201 and the first polymer 202.

In this embodiment, the first pad 201 has a first rounded edge RS1 connecting the first edge 2011S1 of the first portion 2011 and the first edge 2013S1 of the second portion 2013 and a third rounded edge RS3 connecting the first edge 2015S1 of the third portion 2015 and the first edge 2013S1 of the second portion 2013, as shown in FIG. 3, but the disclosure is not limited thereto. The first rounded edge RS1 can avoid stress concentration or charge accumulation at the connection between the first portion 2011 and the second portion 2013, and the third rounded edge RS3 can avoid stress concentration or charge accumulation at the connection between the second portion 2013 and the third portion 2015, thereby reducing the risk of cracking or delamination of the connection structure 20 and reducing the electrostatic discharge.

The second pad 203 is disposed on the first portion 2011 of the first pad 201 and contacts the second edge 2011S2 of the first portion 2011. The second pad 203 may include a lower portion 2031 and an upper portion 2033. In the Z direction, the lower portion 2031 is disposed between the upper portion 2033 and the first portion 2011. In some embodiments, the maximum thickness H1 of the first pad 201 is greater than the maximum thickness H2 of the second pad 203, but the disclosure is not limited thereto. In some embodiments, in the first direction, the width of a vertical projection of the lower portion 2031 of the second pad 203 on the conductive pad 103 may be smaller than the width of a vertical projection of the first portion 2011 of the first pad 201 on the conductive pad 103, but the present disclosure is not limited thereto. In some embodiments, in the first direction, the width of a vertical projection of the lower portion 2031 of the second pad 203 on the conductive pad 103 may be greater than or equal to the width of a vertical projection of the first portion 2011 of the first pad 201 on the conductive pad 103. In some embodiments, in the first direction, the width of a vertical projection of the upper portion 2033 of the second pad 203 on the conductive pad 103 may be smaller than the width of a vertical projection of the entire first pad 201 on the conductive pad 103, but the present disclosure is not limited thereto.

Except for the above structures, the structures of the first pad 201 and the second pad 203 shown in FIG. 3 are substantially the same as the structures of the first pad 201 and the second pad 203 described above with reference to FIGS. 1A and 1B, so it will not be repeated herein.

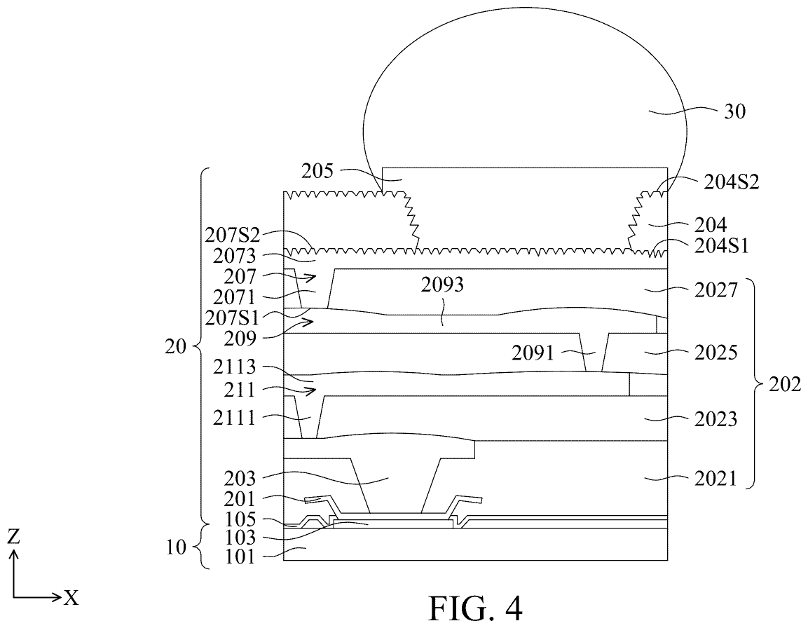

FIG. 4 is a cross-sectional schematic view of an electronic device according to yet another embodiment of the present disclosure. In some embodiments, the connection structure 20 in the electronic device of the present disclosure may further include a third pad 205 electrically connected to the second pad 203 and a bump 30 connected to the third pad 205. The third pad 205 may be disposed between the bump 30 and the second pad 203 and electrically connect the bump 30 and the second pad 203. In some embodiments, the center of the conductive pad 103 is horizontally offset from the center of the bump 30. That is, the center of a vertical projection of the bump 30 on the conductive pad 103 does not overlap with the center of the conductive pad 103, but the present disclosure is not limited thereto. The bump 30 may be disposed on the connection structure 20 and electrically connected the electronic unit 10 with other electronic units and/or electronic devices through the connection structure 20. In some embodiments, the bump 30 may include tin bumps.

In some embodiments, the connection structure 20 in the electronic device of the present disclosure may further include a second polymer 204 disposed between the first polymer 202 and the bump 30. At least part of the third pad 205 may be disposed in the second polymer 204. The second polymer 204 may be disposed between the at least part of the third pad 205 and the first polymer 202. That is, the second polymer 204 may surround the at least part of the third pad 205. The second polymer 204 may have a first surface 204S1 and a second surface 204S2 opposite the first surface 204S1, where the first surface 204S1 is between the second surface 204S2 and the first polymer 202. In some embodiments, the second surface 204S2 of the second polymer 204 may be roughened to form a rough surface, but the present disclosure is not limited thereto. In some embodiments, the first surface 204S1 of the second polymer 204 may also be roughened to form a rough surface. The rough surface can have the effect of blocking the diffusion of thermal stress from the outside to the inside along the surface of different materials. In some embodiments, the roughness of the second surface 204S2 of the second polymer 204 may be greater than the roughness of the surface of the first polymer 202, but the present disclosure is not limited thereto. In some embodiments, the roughness of the first surface 204S1 of the second polymer 204 may be greater than the roughness of the surface of the first polymer 202.

The second polymer 204 may include photosensitive polyimide (PSPI), polyimide (PI), Ajinomoto build-up film (ABF), polybenzoxazole (PBO), other suitable materials, or a combination thereof, but the disclosure is not limited thereto. In some embodiments, the material of the first polymer 202 may be different than the material of the second polymer 204. In some embodiments, the Young's modulus of the first polymer 202 may be less than the Young's modulus of the second polymer 204. Thereby, the structural rigidity of the connection structure 20 can be improved, and the risk of deformation of the connection structure 20 during connection with other electronic devices can be reduced.

In some embodiments, the connection structure 20 in the electronic device of the present disclosure may further include a fourth pad 207. The fourth pad 207 has a first portion 2071 disposed in and surrounded by the first polymer 202 and a second portion 2073 disposed between the first polymer 202 and the second polymer 204. In some embodiments, the third pad 205 may be disposed on the second portion 2073 of the fourth pad 207 and in direct contact with the second portion 2073 of the fourth pad 207. The second pad 203 may be electrically connected to the third pad 205 through the fourth pad 207. In some embodiments, the fourth pad 207 has a second surface 207S2 in contact with the second polymer 204 and a first surface 207S1 opposite the second surface 207S2. In some embodiments, the second surface 207S2 of the fourth pad 207 may be roughened to form a rough surface. The rough surface can have the effect of blocking the diffusion of thermal stress from the outside to the inside along the surface of different materials. In some embodiments, the roughness of the second surface 207S2 of the fourth pad 207 may be greater than the roughness of the first surface 207S1 of the fourth pad 207, but the present disclosure is not limited thereto.

In some embodiments, the first polymer 202 between second polymer 204 and the electronic unit 10 may include multiple layers. In this embodiment, the second pad 203 may be electrically connected the third pad 205 through conductive pads disposed in the first polymer 202 and/or disposed between the first polymer 202 and the second polymer 204. For example, as shown in FIG. 4, the first polymer 202 between the second polymer 204 and the electronic unit 10 may include a first layer 2021, a second layer 2023, a third layer 2025, and a fourth layer 2027. The first layer 2021 of the first polymer 202 surrounds the first pad 201 and the second pad 203, the third layer 2025 is disposed between the first layer 2021 and the second polymer 204, the second layer 2023 is disposed between the first layer 2021 and the three layers 2025, and the fourth layer 2027 is disposed between the third layer 2025 and the second polymer 204. The fourth pad 207 has a first portion 2071 disposed in and surrounded by the fourth layer 2027 and a second portion 2073 disposed between the fourth layer 2027 and the second polymer 204. The fifth pad 209 has a first portion 2091 disposed in and surrounded by the third layer 2025 and a second portion 2093 disposed between the third layer 2025 and the fourth layer 2027. The sixth pad 211 has a first portion 2111 disposed in and surrounded by the second layer 2023 and a second portion 2113 disposed between the second layer 2023 and the third layer 2025.

The second pad 203 electrically connected the third pad 205 through the fourth pad 207, the fifth pad 209 and the sixth pad 211 disposed in the first layer 2021, the second layer 2023, the third layer 2025, and the fourth layer 2027 of the first polymer 202 and/or are between the fourth layer 2027 of the first polymer 202 and the second polymer 204. The bump 30 is electrically connected to the second pad 203 through the third pad 205, the fourth pad 207, the fifth pad 209 and the sixth pad 211.

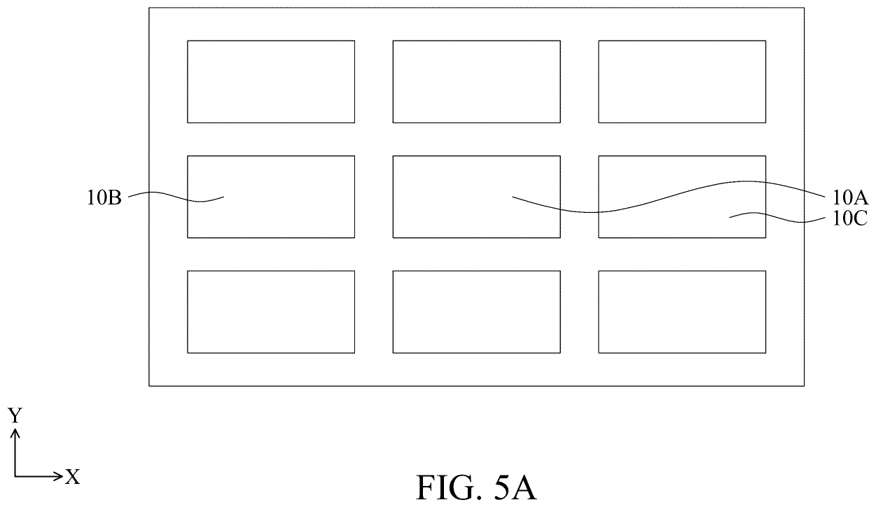

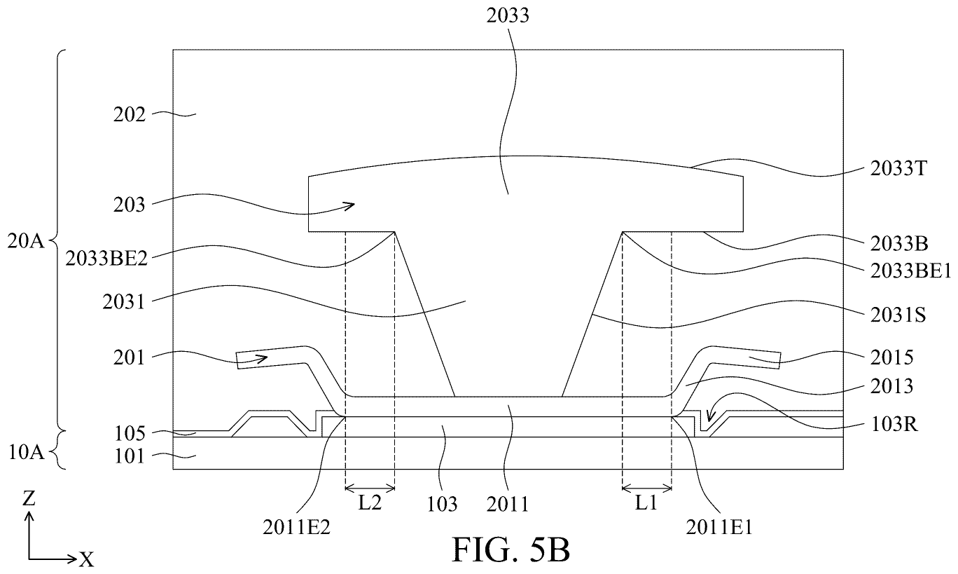

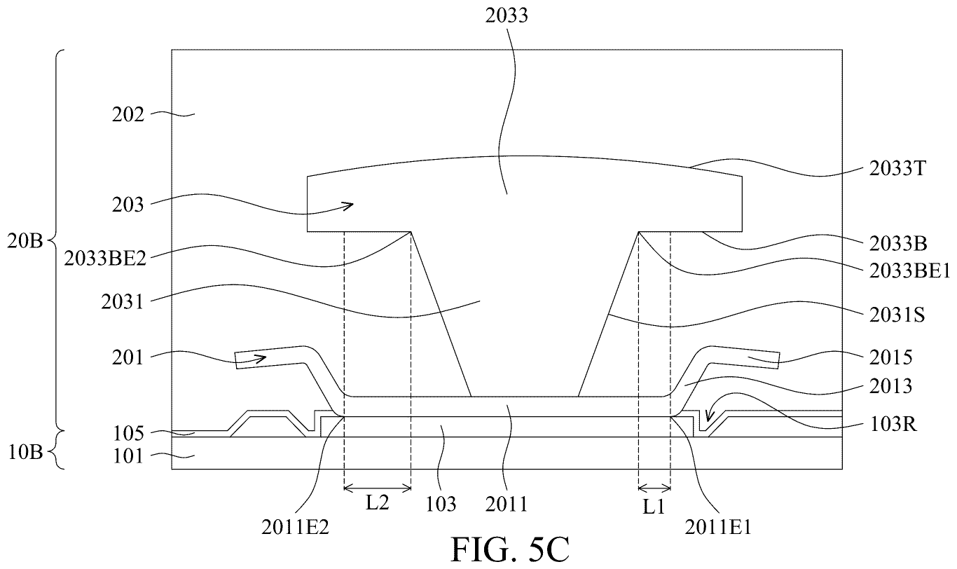

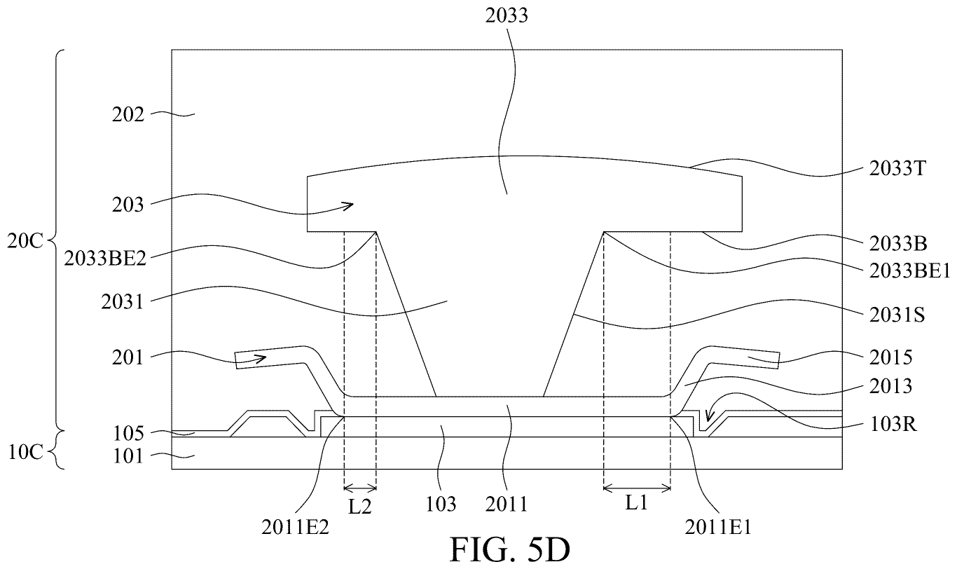

The electronic device of the present disclosure may include a plurality of electronic units and connection structures. FIG. 5A is a schematic layout view of a first electronic unit 10A, a second electronic unit 10B, and a third electronic unit 10C in an electronic device according to another embodiment of the present disclosure.

As shown in FIG. 5A, the electronic device includes a plurality of electronic units arranged in a matrix, where the plurality of electronic units include a first electronic unit 10A, a second electronic unit 10B, and a third electronic unit 10C. The first electronic unit 10A is disposed between the second electronic unit 10B and the third electronic unit 10C along the first direction (X direction), as shown in FIG. 5A. FIG. 5B is a cross-sectional schematic view of the first electronic unit 10A and the first connection structure 20A disposed thereon according to an embodiment of the present disclosure.

As shown in FIG. 5B, the first connection structure 20A is disposed on the first electronic unit 10A. The first connection structure 20A includes a first pad 201 electrically connected to the conductive pad 103 of the first electronic unit 10A, a second pad 203 electrically connected to the first pad 201, and a first polymer 202 surrounding the first pad 201 and the second pad 203. The first pad 201 includes a first portion 2011, a second portion 2013, and a third portion 2015, and the first portion 2011 has a first endpoint 2011E1 and a second endpoint 2011E2 opposite the first endpoint 2011E1. The second pad 203 includes an upper portion 2033 and a lower portion 2031. The lower portion 2031 has a side edge 2031S. The upper portion 2033 has a bottom surface 2033B and a top surface 2033T opposite the bottom surface 2033B, where the bottom surface 2033B contacts the lower portion 2031. The bottom surface 2033B of the upper portion 2033 has a first endpoint 2033BE1 and a second endpoint 2033BE2 opposite the first endpoint 2033BE1. In the cross-sectional view, the first endpoint 2033BE1 and the second endpoint 2033BE2 are respectively the points of intersection of the bottom surface 2033B of the upper portion 2033 and the side edge 2031S of the lower portion 2031. The second endpoint 2011E2 of the first portion 2011 is adjacent to the second electronic unit 10B, and the first endpoint 2011E1 of the first portion 2011 is adjacent to the third electronic unit 10C. That is, in the first direction, a distance between the second endpoint 2011E2 of the first portion 2011 and the second electronic unit 10B is smaller than a distance between the first endpoint 2011E1 of the first portion 2011 and the second electronic unit 10B, and a distance between the first endpoint 2011E1 of the first portion 2011 and the third electronic unit 10C is smaller than a distance between the second endpoint 2011E2 of the first portion 2011 and the third electronic unit 10C. The first endpoint 2033BE1 and the second endpoint 2033BE2 of the second pad 203 are disposed between the first endpoint 2011E1 and the second endpoint 2011E2 of the first portion 2011 of the first pad 201. The first endpoint 2033BE1 of the second pad 203 is adjacent the first endpoint 2011E1 of the first portion 2011 of the first pad 201 and the second endpoint 2033BE2 of the second pad 203 is adjacent the second endpoint 2011E2 of the first portion 2011 of the first pad 201. That is, in the first direction, a distance between the first endpoint 2033BE1 of the second pad 203 and the first endpoint 2011E1 of the first portion 2011 of the first pad 201 is smaller than a distance between the first endpoint 2033BE1 of the second pad 203 and the second endpoint 2011E2 of the first portion 2011 of the first pad 201, and a distance between the second endpoint 2033BE2 of the second pad 203 and the second endpoint 2011E2 of the first portion 2011 is smaller than a distance between the second endpoint 2033BE2 of the second pad 203 and the first endpoint 2011E1 of first portion 2011 of first pad 201.

In the first direction, the first endpoint 2033BE1 of the second pad 203 is separated from the first endpoint 2011E1 of the first portion 2011 of the first pad 201 by a first spacing L1, and the second endpoint 2033BE2 of the second pad 203 is separated from the second endpoint 2011E2 of the first portion 2011 of the first pad 201 by a second spacing L2. In some embodiments, in an embodiment in which the first connection structure 20A is disposed on the first electronic unit 10A in the center of the matrix, the ratio of the first spacing L1 to the second spacing L2 in the first connection structure 20A (L1/L2) is about equal to 1, as shown in FIG. 5A and FIG. 5B, but the present disclosure is not limited thereto.

FIG. 5C is a cross-sectional schematic view of a second electronic unit 10B and a second connection structure 20B disposed thereon according to an embodiment of the present disclosure. As shown in FIG. 5C, the second connection structure 20B is disposed on the second electronic unit 10B. The second connection structure 20B has substantially the same structure as the first connection structure 20A, and the first endpoint 2011E1 of the first portion 2011 of the second connection structure 20B is adjacent to the first electronic unit 10A. That is, in the first direction, a distance between the first endpoint 2011E1 of the first portion 2011 of the first pad 201 of the second connection structure 20B and the first electronic unit 10A is smaller than a distance between the second endpoint 2011E2 of the first portion 2011 of the first pad 201 of the second connection structure 20B and the first electronic unit 10A. In some embodiments, in the embodiments in which the first endpoint 2011E1 of the first portion 2011 of the first pad 201 of the second connection structure 20B is adjacent to the first electronic unit 10A, the second spacing L2 in the second connection structure 20B is greater than the first spacing L1 as shown in FIG. 5A and FIG. 5C, but the present disclosure is not limited thereto. In some embodiments, the ratio of the first spacing L1 to the second spacing L2 (L1/L2) may be greater than or equal to 0.3 and less than or equal to 0.9. Thereby, the stress resistance of the second electronic unit 10B can be improved.

FIG. 5D is a cross-sectional schematic view of a third electronic unit 10C and a third connection structure 20C disposed thereon according to an embodiment of the present disclosure. As shown in FIG. 5D, the third connection structure 20C is disposed on the third electronic unit 10C. The third connection structure 20C has substantially the same structure as the first connection structure 20A, and the second endpoint 2011E2 of the first portion 2011 of the third connection structure 20C is adjacent to the first electronic unit 10A. That is, in the first direction, a distance between the second endpoint 2011E2 of the first portion 2011 of the first pad 201 of the third connection structure 20C and the first electronic unit 10A is smaller than a distance between the first endpoint 2011E1 of the first portion 2011 of the first pad 201 of the third connection structure 20C and the first electronic unit 10A. In some embodiments, in the embodiments in which the second endpoint 2011E2 of the first portion 2011 of the first pad 201 of the third connection structure 20C is adjacent to the first electronic unit 10A, the second spacing L2 in the third connection structure 20C is smaller than the first spacing L1 as shown in FIG. 5A and FIG. 5D, but the present disclosure is not limited thereto. The ratio of the second spacing L2 to the first spacing L1 (L2/L1) may be greater than or equal to 0.3 and less than or equal to 0.9. Thereby, the stress resistance of the third electronic unit 10C can be improved.

The electronic device of the present disclosure having the above structure has a connection structure 20 with stronger structural rigidity and/or lower risk of cracking or delamination. Accordingly, the reliability and electrical properties of the electronic device of the present disclosure can be improved, thereby improving the quality of the electronic device.

Although embodiments of the present disclosure and the advantages thereof have been disclosed as above, it should be understood that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, each of the claims constitutes an individual embodiment, and the protection scope of the present disclosure also includes a combination of each claim and embodiment. As long as the features of each of the embodiments do not violate the spirit of the disclosure or conflict with each other, they can be mixed and matched arbitrarily.

What is claimed is:

1. An electronic device, comprising:
an electronic unit comprising an electronic element and a conductive pad electrically connected to the electronic element; and
a connection structure disposed on the electronic unit and comprising:
a first pad electrically connected to the conductive pad and comprising a first portion, a second portion, and a third portion, wherein the first portion contacts the conductive pad, the second portion connects the first portion, and the third portion connects the second portion and extends outwardly with respect to the first portion;
a second pad electrically connected to the first pad; and
a first polymer surrounding the first pad and the second pad, wherein a portion of the first polymer is disposed between the third portion and the conductive pad, wherein
in a cross-sectional view, the third portion of the first pad has a first edge adjacent to the conductive pad, and at least a portion of the first edge is inclined toward the conductive pad.

2. The electronic device as claimed in claim 1, wherein the at least a portion of the first edge of the third portion is inclined toward the conductive pad at an inclination angle greater than 0 degrees and less than or equal to 20 degrees relative to an extending direction of an edge of the conductive pad.

3. The electronic device as claimed in claim 1, wherein the first edge of the third portion has a first endpoint and a second endpoint spaced apart from the first endpoint, the first endpoint is farthest away from the first portion of the first pad, and a first distance between the first endpoint and the conductive pad is smaller than a second distance between the second endpoint and the conductive pad.

4. The electronic device as claimed in claim 3, wherein the first endpoint is separated from the second endpoint by a third distance, and the third distance is greater than 0 μm and less than or equal to 5 μm.

5. The electronic device as claimed in claim 3, wherein a difference between the first distance and the second distance is less than 2 μm.

6. The electronic device as claimed in claim 1, wherein a maximum thickness of the first pad is less than a maximum thickness of the second pad.

7. The electronic device as claimed in claim 1, wherein a ratio of a width sum of the second width of the second portion and the third width of the third portion to the first width of the first portion is greater than or equal to 0.2 and less than or equal to 0.6.

8. The electronic device as claimed in claim 1, wherein the first pad has a first rounded edge connecting the first edge of the first portion and the first edge of the second portion, and a second rounded edge connecting the second edge of the first portion and the second edge of the second portion, wherein a first radius of curvature of the first rounded edge is smaller than a second radius of curvature of the second rounded edge.

9. The electronic device as claimed in claim 8, wherein a ratio of the first radius of curvature to the second radius of curvature is greater than or equal to 0.3 and less than 1.

10. The electronic device as claimed in claim 1, wherein the first pad has a third rounded edge connecting the first edge of the third portion and the first edge of the second portion, and a fourth rounded edge connecting the second edge of the third portion and the second edge of the second portion, wherein a third radius of curvature of the third rounded edge is smaller than a fourth radius of curvature of the fourth rounded edge.

11. The electronic device as claimed in claim 10, wherein a ratio of the third radius of curvature to the fourth radius of curvature is greater than or equal to 0.1 and less than 1.

12. The electronic device as claimed in claim 1, wherein in the cross-sectional view, the second pad has an edge away from the first pad, and the edge of the second pad is non-linear.

13. The electronic device as claimed in claim 1, wherein the electronic unit further comprises a passivation layer disposed on the conductive pad, and the passivation layer has an opening, wherein the first pad electrically connects to the conductive pad through the opening.

14. The electronic device as claimed in claim 13, wherein the passivation layer comprises a first layer and a second layer disposed on the first layer, and a first thickness of the first layer is greater than a second thickness of the second layer.

15. The electronic device as claimed in claim 14, wherein a ratio of the first thickness to the second thickness is greater than 1 and less than or equal to 2.

16. The electronic device as claimed in claim 14, wherein the first layer comprises a silicon oxide and the second layer comprises a silicon nitride.

17. The electronic device as claimed in claim 1, wherein the connection structure comprises a third pad electrically connected to the second pad and a bump connected to the third pad, wherein a center of the conductive pad is horizontally offset from a center of the bump.

18. The electronic device as claimed in claim 17, further comprising a second polymer disposed between the first polymer and the bump, wherein a material of the first polymer is different than a material of the second polymer.

19. The electronic device as claimed in claim 18, wherein a Young's modulus of the first polymer is less than a Young's modulus of the second polymer.

20. The electronic device as claimed in claim 1, wherein the electronic unit comprises a semiconductor chip.
